(19) United States
(12) Patent Application Publication
(10) Pub. No.: US 2024/0363309 A1
(43) Pub. Date: Oct. 31, 2024

(54) SUBSTRATE PROCESSING APPARATUS, SEMICONDUCTOR DEVICE MANUFACTURING METHOD, AND SUBSTRATE PROCESSING METHOD

(71) Applicant: Kokusai Electric Corporation, Tokyo (JP)

(72) Inventors: Naofumi OHASHI, Toyama (JP); Tsuyoshi TAKEDA, Toyama (JP); Teruo YOSHINO, Toyama (JP)

(21) Appl. No.: 18/620,246

(22) Filed: Mar. 28, 2024

Related U.S. Application Data
(63) Continuation of application No. PCT/JP2022/025191, filed on Jun. 23, 2022.

(30) Foreign Application Priority Data
Nov. 26, 2021 (JP) 2021-192313

(51) Int. Cl. H01J 37/32

(52) U.S. Cl. CPC H01J 37/3211; H01J 37/32183

(57) ABSTRACT

A uniformity of a substrate processing within a substrate surface can be improved. There is provided a technique that includes: a process vessel in which a process gas is excited into a plasma state; a gas supplier supplying the process gas into the process vessel; and a plasma generation structure wound in a spiral shape along an outer periphery of the process vessel and including at least two coils to which high-frequency powers are respectively supplied, wherein diameters of the at least two coils are substantially the same, lengths of the at least two coils are substantially same, and a value of a net amplitude obtained by overlapping an amplitude of a superposition of standing waves respectively generated by each of the at least two coils is set to be smaller than a peak of the amplitude of each of the standing waves.

### CROSS-REFERENCE TO RELATED APPLICATION(S)

This application is based on PCT International Application No. PCT/JP2022/025191, filed on Jun. 23, 2022 and designating the United States, the international application being based upon and claiming the benefit of priority from Japanese Patent Application No. 2021-192313, filed on Nov. 26, 2021, the entire content of which is incorporated herein by reference.

### TECHNICAL FIELD

The present disclosure relates to a substrate processing apparatus, a method of manufacturing a semiconductor device, a substrate processing method and a non-transitory computer-readable recording medium.

### BACKGROUND

According to some related arts, as a part of a manufacturing process of a semiconductor device, a substrate processing may be performed by exciting a process gas into a plasma state by supplying a high frequency power to a coil.

### SUMMARY

However, when a plasma density increases in the vicinity of a grounding position on a coil, a uniformity of a substrate processing within a surface of a substrate may be reduced.

It is an object of the present disclosure to provide a technique capable of improving the uniformity of the substrate processing within the surface of the substrate.

According to one embodiment of the present disclosure, there is provided a technique that includes: a process vessel in which a process gas is excited into a plasma state; a gas supplier configured to supply the process gas into the process vessel; and a plasma generation structure provided so as to be wound in a spiral shape along an outer periphery of the process vessel and including at least two coils to which high frequency powers are respectively supplied, wherein diameters of the at least two coils are set to be substantially same, lengths of the at least two coils are set to be substantially same, and a net amplitude obtained by superposition of standing waves respectively generated by the at least two coils is set to be smaller than a peak amplitude of each of the standing waves.

According to the present disclosure, it is possible to improve a uniformity of a substrate processing within a surface of a substrate.

### BRIEF DESCRIPTION OF DRAWINGS

FIG. 1 is a diagram schematically illustrating a configuration of a substrate processing apparatus preferably used in one embodiment of the present disclosure.

FIG. 2 is a diagram illustrating a principle of generating a plasma according to the embodiment of the present disclosure.

FIG. 3 is a diagram for explaining a double coil preferably used in the embodiment of the present disclosure.

FIG. 4A is a diagram illustrating a power feeding position and a grounding position in a circumferential direction of each of two coils constituting the double coil shown in FIG. 3, and

FIG. 4B is a diagram illustrating a standing wave of a high frequency current in each of the two coils constituting the double coil shown in FIG. 3.

FIG. 5 is a block diagram schematically illustrating a configuration of a controller and related components of the substrate processing apparatus preferably used in the embodiment of the present disclosure.

FIG. 6 is a flow chart schematically illustrating a substrate processing preferably used the embodiment of the present disclosure.

FIG. 7A is a diagram illustrating a power feeding position and a grounding position in a circumferential direction of each of two coils constituting a double coil according to a modified example, and FIG. 7B is a diagram illustrating a standing wave of a high frequency current in each of the two coils constituting the double coil shown in FIG. 7A.

FIG. 8 is a diagram illustrating a power feeding position and a grounding position in a circumferential direction of each of two coils constituting a double coil according to another modified example.

### DETAILED DESCRIPTION

### One Embodiment of Present Disclosure

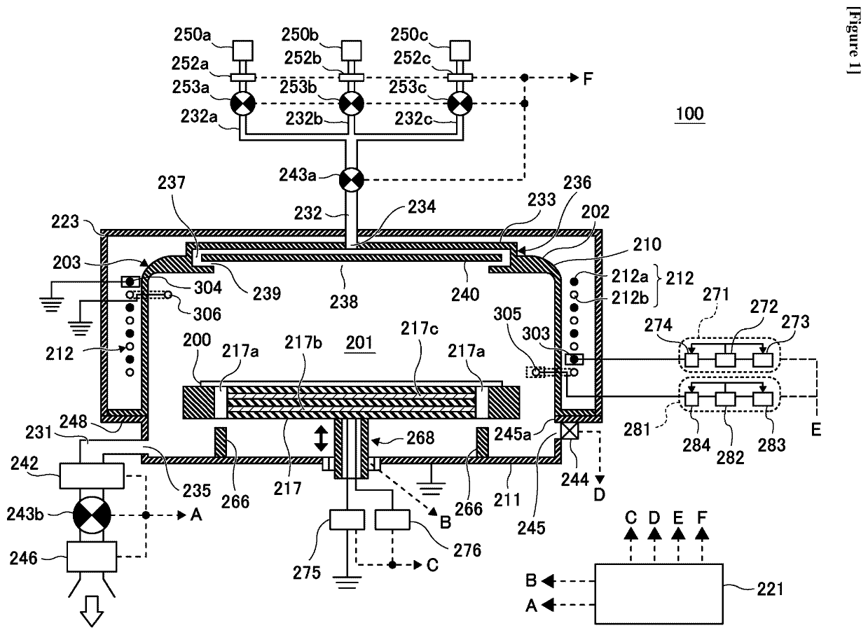

Hereinafter, one embodiment according to the present disclosure will be described with reference to FIGS. 1 to 6. Further, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match.

### (1) Configuration of Substrate Processing Apparatus

Hereinafter, a configuration of a substrate processing apparatus 100 according to the embodiment of the present disclosure will be described below with reference to FIG. 1. The substrate processing apparatus 100 according to the embodiment of the present disclosure is configured to perform a substrate processing by using a plasma mainly on a base or a film formed on a surface of a substrate.

### <Process Chamber>

The substrate processing apparatus 100 includes a process furnace 202 in which a wafer 200 serving as the substrate is processed by the plasma. The process furnace 202 is provided with a process vessel 203 constituting a process chamber 201. The process vessel 203 is provided with a plasma generation space 201a in which a process gas is excited into a plasma state. The process vessel 203 may include a dome-shaped upper vessel 210 serving as a first vessel and a bowl-shaped lower vessel 211 serving as a second vessel. By covering the lower vessel 211 with the upper vessel 210, the process chamber 201 is defined. The upper vessel 210 may be made of quartz.

In addition, a gate valve 244 is provided on a lower side wall of the lower vessel 211. While the gate valve 244 is open, the wafer 200 can be transferred (loaded) into the process chamber 201 through a loading/unloading port 245 using a wafer transfer structure (not shown) or can be transferred (unloaded) out of the process chamber 201 through the loading/unloading port 245 using the wafer transfer structure. While the gate valve 244 is closed, the gate valve 244 maintains the process chamber 201 airtight.

The process chamber 201 may include the plasma generation space 201a and a substrate processing space 201b. A double coil 212 serving as a coil serving as an electrode is provided around the plasma generation space 201a. The substrate processing space 201b communicates with the plasma generation space 201a, and serves as a substrate process chamber where the wafer 200 is processed. The plasma generation space 201a refers to a space in which the plasma is generated, for example, a space above a lower end of the double coil 212 and below an upper end of the double coil 212 in the process chamber 201. In addition, the substrate processing space 201b refers to a space in which the wafer 200 is processed by using the plasma, for example, a space below the lower end of the double coil 212. According to the embodiment of the present disclosure, a horizontal diameter of the plasma generation space 201a in a horizontal direction is set to be substantially the same as a horizontal diameter of the substrate processing space 201b in the horizontal direction. The double coil 212 will be described below in detail.

### <Susceptor>

A susceptor 217 serving as a substrate mounting table on which the wafer 200 is placed is provided at a center of a bottom portion of the process chamber 201. The susceptor 217 is provided below the double coil 212 in the process chamber 201.

A heater 217b serving as a heating structure is integrally embedded in the susceptor 217. The heater 217b is configured to heat the wafer 200 when an electric power is supplied to the heater 217b.

The susceptor 217 is electrically insulated from the lower vessel 211. An impedance adjusting electrode 217c is provided in the susceptor 217 so as to further improve a uniformity of a plasma density of the plasma generated on the wafer 200 placed on the susceptor 217, and is grounded via a variable impedance regulator 275 serving as an impedance adjusting structure.

A susceptor elevator 268 including a driver (which is a driving structure) capable of elevating and lowering the susceptor 217 is provided at the susceptor 217. In addition, through-holes 217a are provided at the susceptor 217, and wafer lift pins 266 are provided at a bottom surface of the lower vessel 211 at locations corresponding to the through-holes 217a. When the susceptor 217 is lowered by the susceptor elevator 268, the wafer lift pins 266 pass through the through-holes 217a without contacting the susceptor 217.

### <Gas Supplier>

A gas supply head 236 is provided above the process chamber 201, that is, on an upper portion of the upper vessel 210. The gas supply head 236 may include a cap-shaped lid 233, a gas inlet port 234, a buffer chamber 237, an opening 238, a shield plate 240 and a gas outlet port 239, and is configured such that the process gas is capable of being supplied into the process chamber 201 through the gas supply head 236. The buffer chamber 237 functions as a dispersion space in which the process gas introduced (supplied) through the gas inlet port 234 is dispersed.

A downstream end of an oxygen-containing gas supply pipe 232a through which an oxygen-containing gas serving as a part of the process gas is supplied, a downstream end of a hydrogen-containing gas supply pipe 232b through which a hydrogen-containing gas serving as a part of the process gas is supplied and a downstream end of an inert gas supply pipe 232c through which an inert gas serving as a part of the process gas is supplied are connected to a gas supply pipe 232 of the gas inlet port 234 so as to be conjoined with one another. An oxygen-containing gas supply source 250a, a mass flow controller (MFC) 252a serving as a flow rate controller and a valve 253a serving as an opening/closing valve are sequentially provided at the oxygen-containing gas supply pipe 232a in this order from an upstream side to a downstream side of the oxygen-containing gas supply pipe 232a in a gas flow direction. A hydrogen-containing gas supply source 250b, an MFC 252b and a valve 253b are sequentially provided at the hydrogen-containing gas supply pipe 232b in this order from an upstream side to a downstream side of the hydrogen-containing gas supply pipe 232b in a gas flow direction. An inert gas supply source 250c, an MFC 252c and a valve 253c are sequentially provided at the inert gas supply pipe 232c in this order from an upstream side to a downstream side of the inert gas supply pipe 232c in a gas flow direction. A valve 243a is provided at the gas supply pipe 232 at a downstream side of a location where the oxygen-containing gas supply pipe 232a, the hydrogen-containing gas supply pipe 232b and the inert gas supply pipe 232c join. The valve 243a is connected to an upstream side of the gas inlet port 234. By opening and closing the valves 253a, 253b, 253c and 243a, it is possible to adjust flow rates of the oxygen-containing gas, the hydrogen-containing gas and the inert gas by the MFCs 252a, 252b and 252c, respectively. In addition, it is configured such that the process gas such as the oxygen-containing gas, the hydrogen-containing gas and the inert gas is capable of being supplied into the process chamber 201 through the oxygen-containing gas supply pipe 232a, the hydrogen-containing gas supply pipe 232b and the inert gas supply pipe 232c.

A gas supplier (which is a gas supply system or a gas supply structure) according to the embodiment of the present disclosure is constituted mainly by the gas supply head 236, the oxygen-containing gas supply pipe 232a, the hydrogen-containing gas supply pipe 232b, the inert gas supply pipe 232c, the MFCs 252a, 252b and 252c and the valves 253a, 253b, 253c and 243a. That is, the gas supplier (gas supply system) is configured to supply the process gas into the process vessel 203.

Further, an oxygen-containing gas supplier (which is an oxygen-containing gas supply system or an oxygen-containing gas supply structure) according to the embodiment of the present disclosure is constituted mainly by the gas supply head 236, the oxygen-containing gas supply pipe 232a, the MFC 252a and the valves 253a and 243a. In addition, a hydrogen-containing gas supplier (which is a hydrogen-containing gas supply system or a hydrogen-containing gas supply structure) according to the embodiment of the present disclosure is constituted mainly by the gas supply head 236, the hydrogen-containing gas supply pipe 232b, the MFC 252b and the valves 253b and 243a. In addition, an inert gas supplier (which is an inert gas supply system or an inert gas supply structure) according to the embodiment of the present disclosure is constituted mainly by the gas supply head 236, the inert gas supply pipe 232c, the MFC 252c and the valves 253c and 243a.

### <Exhauster>

A gas exhaust port 235 through which the process gas is exhausted from an inside of the process chamber 201 is provided on the side wall of the lower vessel 211. An upstream end of a gas exhaust pipe 231 is connected to the gas exhaust port 235. An APC (Automatic Pressure Controller) valve 242 serving as a pressure regulator (pressure adjusting structure), a valve 243b serving as an opening/closing valve and a vacuum pump 246 serving as a vacuum exhaust apparatus are sequentially provided at the gas exhaust pipe 231 in this order from an upstream side to a downstream side of the gas exhaust pipe 231 in the gas flow direction. An exhauster (which is an exhaust system or an exhaust structure) according to the embodiment of the present disclosure is constituted mainly by the gas exhaust port 235, the gas exhaust pipe 231, the APC valve 242 and the valve 243b. In addition, the exhauster may further include the vacuum pump 246.

### <Plasma Generator>

The double coil 212 is provided on an outer periphery of the process chamber 201, that is, on an outside of a side wall of the upper vessel 210, so as to be wound a plurality of times in a spiral shape along an outer periphery of the upper vessel 210. The double coil 212 is constituted by a first coil 212a and a second coil 212b.

An RF (Radio Frequency) sensor 272, a high frequency power supply 273 and a matcher (which is a matching structure) 274 are connected to the first coil 212a. The matcher 274 is configured to perform an impedance matching or an output frequency matching for the high frequency power supply 273. An RF sensor 282, a high frequency power supply 283 and a matcher 284 are connected to the second coil 212b. The matcher 284 is configured to perform an impedance matching or an output frequency matching for the high frequency power supply 283.

The high frequency power supplies 273 and 283 are configured to supply a high frequency power (RF power) to the first coil 212a and a high frequency power (RF power) to the second coil 212b, respectively. The RF sensors 272 and 282 are provided at output sides of the high frequency power supplies 273 and 283, respectively, and are configured to monitor information of a traveling wave or reflected wave of the high frequency power supplied from the high frequency power supply 273 and information of a traveling wave or reflected wave of the high frequency power supplied from the high frequency power supply 283, respectively. The information of the reflected wave monitored by the RF sensor 272 and the information of the reflected wave monitored by the RF sensor 282 are input to the matchers 274 and 284 and the high frequency power supplies 273 and 283, respectively. Based on the information of the reflected waves, variable capacitors in the matcher 274 and 284 and output frequencies of the high frequency power supplies 273 and 283 are controlled so as to minimize amplitudes of the reflected waves. In other words, by performing such a control described above, input impedances of the matchers 274 and 284 are matched with output impedances of the high frequency power supplies 273 and 283, respectively.

Each of the high frequency power supplies 273 and 283 may include a power supply controller (which is a control circuit) (not shown) and an amplifier (which is an output circuit) (not shown). The power supply controller may include a high frequency oscillation circuit (not shown) and a preamplifier (not shown) in order to regulate an oscillation frequency and an output. The amplifier amplifies the output to a predetermined output level. The power supply controller controls the amplifier based on output conditions relating to the frequency and the power, which are set in advance through an operation panel (not shown). The amplifiers of the high frequency power supplies 273 and 283 are configured to supply constant high frequency powers to the first coil 212a and the second coil 212b via transmission lines, respectively.

The high frequency power supply 273, the matcher 274 and the RF sensor 272 may be collectively referred to as a “high frequency power supplier 271” which is a high frequency power supply structure or a high frequency power supply system. Alternatively, one of the high frequency power supply 273, the matcher 274 and the RF sensor 272 or a combination thereof may also be referred to as the “high frequency power supplier 271”. The high frequency power supplier 271 may also be referred to as a “first high frequency power supplier” which is a first high frequency power supply structure or a first high frequency power supply system.

In addition, the high frequency power supply 283, the matcher 284 and the RF sensor 282 may be collectively referred to as a “high frequency power supplier 281” which is a high frequency power supply structure or a high frequency power supply system. Alternatively, one of the high frequency power supply 283, the matcher 284 and the RF sensor 282 or a combination thereof may also be referred to as the “high frequency power supplier 281”. The high frequency power supplier 281 may also be referred to as a “second high frequency power supplier” which is a second high frequency power supply structure or a second high frequency power supply system. The first high frequency power supplier 271 and the second high frequency power supplier 281 may also be collectively referred to as a “high frequency power supplier”.

A shield plate 223 is provided to shield its inside from an electric field outside of the double coil 212 and to form a capacitive component (also referred to as a “C component”) of the double coil 212 appropriate for constructing a resonance circuit between the shield plate 223 and the first coil 212a or between the shield plate 223 the second coil 212b. In general, the shield plate 223 is made of a conductive material such as an aluminum alloy, and is of a cylindrical shape. The shield plate 223 is disposed, for example, about 5 mm to 150 mm apart from an outer periphery of the double coil 212.

A first plasma generator is constituted mainly by the first coil 212a and the high frequency power supplier 271. Further, a second plasma generator is constituted mainly by the second coil 212b and the high frequency power supplier 281. The first plasma generator and the second plasma generator may also be collectively referred to as a “plasma generator”.

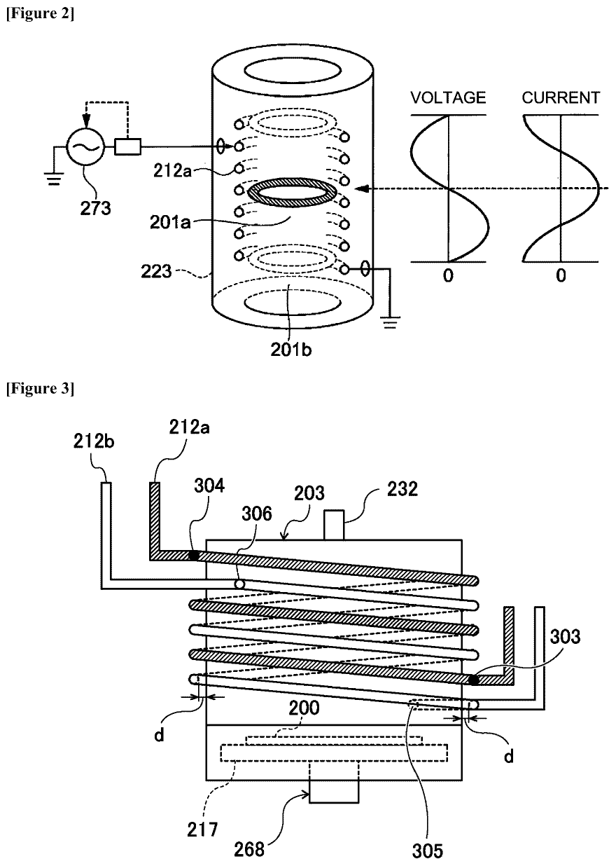

Hereinafter, a principle of generating the plasma and properties of the plasma generated accordingly will be described with reference to FIG. 2. Since the principle of generating the plasma by each of the first coil 212a and the second coil 212b is substantially the same, in the present specification, the principle of generating the plasma by the first coil 212a will be described as an example.

An equivalent circuit constituted by the first coil 212a and the plasma generated by the first coil 212a can be expressed as an RLC parallel circuit, and a generation efficiency of the plasma is maximized at resonance. When a wavelength of the high frequency power supplied from the high frequency power supply 273 and a length of the first coil 212a are the same, resonance conditions of the parallel circuit described above are set such that a reactance component represented by an inductive component L and a capacitive component C is zero, that is, an impedance of the parallel circuit becomes a pure resistance. However, since the inductive component L and the capacitive component C described above may vary greatly depending on a generation state of the plasma, a control structure is preferably used to adjust them so as to satisfy the resonance conditions.

Therefore, according to the present embodiment, as the control structure described above, the RF sensor 272 detects the reflected wave from the first coil 212a when the plasma is generated, and the matcher 274 and the high frequency power supply 273 are controlled based on the information of the reflected wave detected as described above.

Specifically, based on the information of the reflected wave from the first coil 212a detected by the RF sensor 272 when the plasma is generated, the output frequency of the high frequency power supply 273 is increased or decreased by a frequency control circuit of the high frequency power supply 273 such that the amplitude of the reflected wave is minimized. Further, the capacitance is increased or decreased by a variable capacitor control circuit of the matcher 274. Further, the high frequency power supply 273 and the RF sensor 272, or the matcher 274 and the RF sensor 272 may be integrated as a single structure.

With such a configuration, as shown in FIG. 2, since the high frequency power in accordance with an actual resonance frequency of the coil combined with the plasma (or the high frequency power is supplied to match an actual impedance of the coil combined with the plasma) is supplied to the first coil 212a according to the present embodiment, a standing wave in which a phase difference between the high frequency voltage and the high frequency current is close to 90° is generated. When an electrical length of the first coil 212a and the wavelength of the high frequency power are the same, the highest phase of the high frequency current is generated at an electrical midpoint (node whose high frequency voltage is zero) of first coil 212a. Therefore, in the vicinity of the electrical midpoint of the first coil 212a, a donut-shaped plasma which is hardly capacitively coupled with the plasma is formed due to an inductive coupling.

Further, according to the same principle, the donut-shaped plasma due to the inductive coupling is formed at an end position of a spiral of the first coil 212a and in the vicinity of a grounding position.

For example, in the double coil constituted by two coils, in addition to the electrical midpoint of each coil, the donut-shaped plasma due to the inductive coupling is also formed in the vicinity of the grounding position of each coil. Thereby, the plasma density is highest in the vicinity of the grounding position of each coil. Therefore, when grounding points of the two coils are adjacent to each other, the maximum amplitude locally increases due to superposition of the standing waves of both high frequency currents of the two coils. As a result, the plasma density locally increases. Thereby, a uniformity of the substrate processing may be reduced, a component such as a quartz component may deteriorate, and a maintenance frequency of the component may increase. Thus, a downtime of an apparatus such as the substrate processing apparatus 100 may also increase.

As will be described later, the double coil 212 according to the present embodiment is configured to suppress a local increase in the maximum amplitude obtained by the superposition of both of the standing waves. By supplying the high frequency to each of the first coil 212a and the second coil 212b, the donut-shaped plasma due to the inductive coupling is generated in the vicinity of the grounding positions on electric wires and the electrical midpoints of the electric wires of the first coil 212a and the second coil 212b. Thereby, it is possible to flatten a plasma distribution. That is, by supplying the high frequency power to the first coil 212a and the second coil 212b while the process gas is supplied to the plasma generation space 201a, the plasma is generated there by an action of the high frequency voltage and the high frequency current according to the principle described above, and a reaction with the wafer 200 is promoted using the process gas activated by the plasma, that is, the process gas in a radical state.

Further, by using the double coil 212, it is possible to increase a generation amount of the plasma as compared with a single coil. That is, it is possible to increase an amount of radicals generated by the plasma. Therefore, for example, since a sufficient amount of the radicals can be supplied such that the radicals can reach a bottom of a deep groove formed on the wafer 200 (which is the substrate to be processed), it is possible to sufficiently process the bottom of the deep groove.

### <Structure of Double Coil>

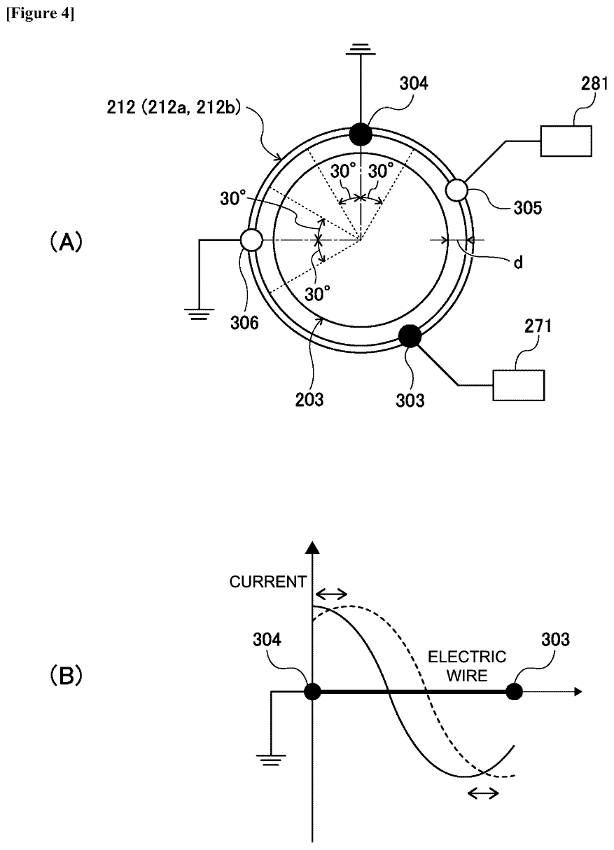

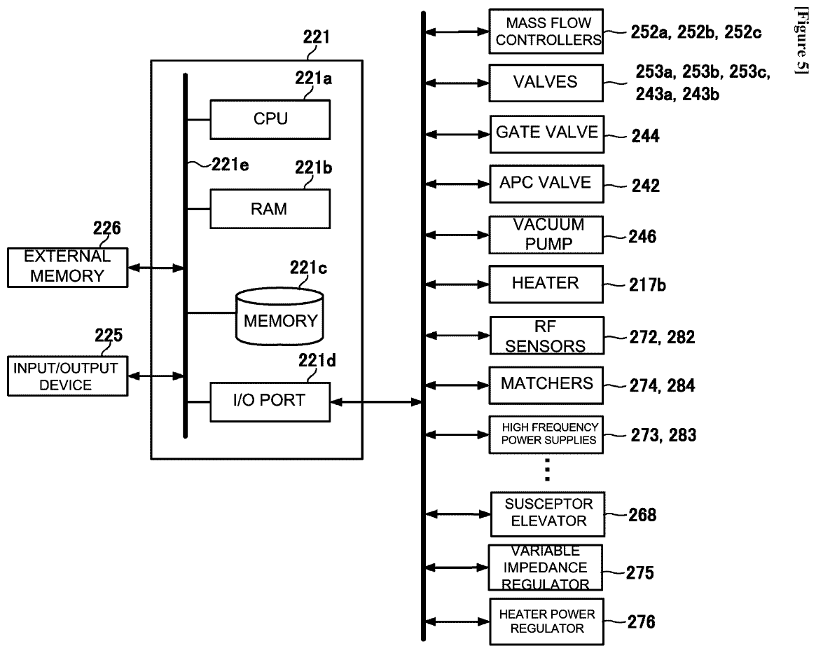

Subsequently, a structure of the double coil 212 (which is a plasma generation structure including at least the two coils) will be described in detail with reference to FIGS. 3, 4A, and 4B.

As described above, the double coil 212 is constituted by the first coil 212a and the second coil 212b, and is provided so as to be wound a plurality of times in the spiral shape along an outer periphery of the process vessel 203. Further, centers of the first coil 212a and the second coil 212b are arranged at a center of the process vessel 203, and the first coil 212a and the second coil 212b are arranged alternately at equal intervals in a vertical direction.

In the present specification, the term “along the outer periphery of the process vessel 203” means that the double coil 212 and the outer periphery (an outer surface or an outer wall) of the process vessel 203 are close to each other such that a high frequency electromagnetic field generated by the double coil 212 is capable of substantially exciting the process gas in the process vessel 203 into the plasma state.

Diameters of the first coil 212a and the second coil 212b are set to be substantially the same, and lengths of the first coil 212a and the second coil 212b are set to be substantially the same. Further, a winding diameter, a winding pitch and the number of winding turns of each of the first coil 212a and the second coil 212b are set such that each of the first coil 212a and the second coil 212b resonates at a constant wavelength to form the standing wave of a predetermined wavelength. That is, it is preferable that a length of each of the first coil 212a and the second coil 212b is set to a length corresponding to an integral multiple (1 time, 2 times, or so on) of ¼ wavelength of a predetermined frequency of the high frequency power supplied from the high frequency power supplies 273 or 283.

Specifically, considering conditions such as the power to be applied, a strength of a magnetic field to be generated and a shape of an apparatus such as the substrate processing apparatus 100 to which the power is to be applied, each of the first coil 212a and the second coil 212b is configured as a coil whose effective cross-section is within a range from 50 mm2 to 300 mm2 and whose diameter is within a range from 200 mm to 500 mm and which is wound, for example, twice to 60 times around an outer periphery of a room constituting the plasma generation space 201a such that a magnetic field of about 0.01 Gauss to about 10 Gauss can be generated by the high frequency power whose frequency is within a range from 800 kHz to 50 MHz and whose power is within a range from 0.1 kW to 10 kW.

In the present specification, the term “the diameters of the first coil 212a and the second coil 212b are set to be substantially the same” means that wire diameters of the first coil 212a and the second coil 212b are set to be substantially the same within an error range of about ±10%. Further, “the lengths of the first coil 212a and the second coil 212b are set to be substantially the same” means that the lengths of the first coil 212a and the second coil 212b from respective power feeding points to respective grounding points are set to be substantially the same within an error range of about ±10%. In a manner described above, by configuring the double coil 212 by the first coil 212a and the second coil 212b whose diameters are substantially the same and whose lengths are substantially the same, it is possible to easily suppress an occurrence of an abnormal discharge. In the present embodiment, “the diameters of the first coil 212a and the second coil 212b are set to be substantially the same” may be expressed simply as “the diameters of the first coil 212a and the second coil 212b are set to be the same”, and “the lengths of the first coil 212a and the second coil 212b are set to be substantially the same” may be expressed simply as “the lengths of the first coil 212a and the second coil 212b are the same”.

The first coil 212a and the second coil 212b are provided such that the winding pitch of each of the first coil 212a and the second coil 212b is at equal intervals. Further, the winding diameter (diameter) of each of the first coil 212a and the second coil 212b is set to be greater than a diameter of the wafer 200 or an outer diameter of the process vessel 203. In addition, the winding diameters of the first coil 212a and the second coil 212b are constant and set to be substantially the same at any position. That is, a coil separation distance “d” of each of the first coil 212a and the second coil 212b from a surface of the outer wall (a surface of the outer periphery) of the upper vessel 210 to a surface of an inner diameter side (a surface facing the side wall of the upper vessel 210, that is, a surface of an inner periphery) of each of the first coil 212a and the second coil 212b is constant, and the winding diameters of the first coil 212a and the second coil 212b are set to be substantially the same. In the present specification, the term “the winding diameters of the first coil 212a and the second coil 212b are set to be substantially the same” means that the winding diameters of the first coil 212a and the second coil 212b are set to be substantially the same within an error range of about ±10%.

For example, as a material constituting each of the first coil 212a and the second coil 212b, a copper pipe, a copper thin plate, an aluminum pipe, an aluminum thin plate, or a material obtained by depositing copper or aluminum on a polymer belt may be used.

The first coil 212a includes: a power feeding point 303 (which is an end position of a spiral of the first coil 212a) where the spiral is spaced apart from the process vessel 203 by more than the coil separation distance d; and a grounding point 304 (which is another end position of the spiral) where the spiral is spaced apart from the process vessel 203 by more than the coil separation distance d. The grounding point 304 is grounded. The high frequency power supplier 271 is connected to the power feeding point 303.

The second coil 212b includes: a power feeding point 305 (which is an end position of a spiral of the second coil 212b) where the spiral is spaced apart from the process vessel 203 by more than the coil separation distance d; and a grounding point 306 (which is another end position of the spiral) where the spiral is spaced apart from the process vessel 203 by more than the coil separation distance d. The grounding point 306 is grounded. The high frequency power supplier 281 is connected to the power feeding point 305.

In the first coil 212a, as shown by a solid line in FIG. 4B, the high frequency power propagating through the first coil 212a is reflected at an end portion and returns to the power feeding point 303. According to the present embodiment, since the end portion of the first coil 212a is grounded, a reflection coefficient is substantially −1, and a phase difference between the traveling wave and the reflected wave is substantially 180°. Waves that are superimposed with such a phase difference are generated on the electric wire of the coil as the standing wave. Further, the phase difference (power factor) between the high frequency voltage and the high frequency current during the resonance is substantially 90°.

In the double coil 212 according to the present embodiment, the grounding point 304 (which is the end position of the spiral of the first coil 212a) and the grounding point 306 (which is the end position of the spiral of the second coil 212b) are arranged such that, with reference to a center axis of the double coil 212, at least a circumferential range of ±30° from the grounding point 304 does not overlap with a circumferential range of ±30° from the grounding point 306, and preferably the grounding point 304 and the grounding point 306 are located at angular positions substantially ±90° or substantially ±180° away from each other. Thereby, a plasma distribution by the first coil 212a and a plasma distribution by the second coil 212b can be flattened in a circumferential direction. That is, in the double coil 212, the grounding point 306 of the second coil 212b is rotated, for example, by ±90° or ±180° around a center axis of an inner diameter of the double coil 212 as the rotation axis such that the circumferential range of ±30° from the grounding point 306 of the second coil 212b does not overlap with the circumferential range of ±30° from the grounding point 304 of the first coil 212a. Since a waveform of the standing wave described above is a sine wave, by arranging the first coil 212a and the second coil 212b as described above, the amplitude obtained by the superposition of each standing wave is set to be less than or equal to the amplitude of one standing wave. That is, it is configured such that a net amplitude obtained by the superposition of the standing waves respectively generated by the first coil 212a and the second coil 212b is set to be smaller than a peak of the amplitude of each standing wave. Specifically, the net amplitude obtained by the superposition of the standing waves respectively generated by the first coil 212a and the amplitude of the standing wave generated by the second coil 212b is set to be smaller than the peak of the amplitude of the standing wave generated by one of the first coil 212a and the second coil 212b.

Thereby, it is possible to obtain an effect of reducing the local increase in the maximum amplitude obtained by the superposition of the standing waves. That is, a line connecting the grounding point 304 of the first coil 212a and the center of the inner diameter of the double coil 212 and a line connecting the grounding point 306 of the second coil 212b and the center of the inner diameter of the double coil 212 are located where at least the circumferential range of ±30° thereof does not overlap with each other. That is, the line connecting the grounding point 304 and the center of the inner diameter of the double coil 212 and the line connecting the grounding point 306 and the center of the inner diameter of the double coil 212 are arranged within a range from 30° to 330°, and more preferably, arranged ±90° or ±180° away from each other.

Further, in the present disclosure, a notation of a numerical range such as “within a circumferential range of ±30°” means that a lower limit and an upper limit are not included in the numerical range. Therefore, for example, a numerical range “within a circumferential range of ±30°” means a range higher than −30° and less than ±30°. In addition, in the present disclosure, a notation of a numerical range such as “from 30° to 330°” means that a lower limit and an upper limit are included in the numerical range. Therefore, for example, a numerical range “from 30° to 330°” means a range equal to or higher than 30° and equal to or less than 330°. The same also applies to other numerical ranges described in the present disclosure.

Then, the first coil 212a and the second coil 212b are supplied with the high frequency powers from the high frequency power supplies 273 and 283 via the power feeding point 303 and the power feeding point 305, respectively. Thereby, a standing wave of the high frequency current or the high frequency voltage is formed between the power feeding point 303 and the grounding point 304 of the first coil 212a, and a standing wave of the high frequency current or the high frequency voltage is formed between the power feeding point 305 and the grounding point 306 of the second coil 212b. By arranging the electrical midpoint of the first coil 212a and the electrical midpoint of the second coil 212b at different positions in the circumferential direction, as shown by a broken line in FIG. 4B, a maximum amplitude position of the standing wave in the first coil 212a (indicated by a solid line in FIG. 4B) is displaced from a maximum amplitude position of the standing wave in the second coil 212b (indicated by a broken line in FIG. 4B), and it is also possible to suppress the local increase in the maximum amplitude obtained by the superposition of the standing waves. As a result, the plasma generated within the process vessel 203 can be flattened in the circumferential direction, so that it is possible to reduce a damage caused by the plasma to the quartz component and the like in the process vessel 203 and the like. Thereby, it is also possible to improve the uniformity of the substrate processing within the surface of the substrate (that is, the wafer 200).

In other words, the first coil 212a and the second coil 212b are arranged such that antinodes of the standing waves do not overlap with each other. Further, a distance between the first coil 212a and the second coil 212b is set to a distance that does not cause an arc discharge between conductors of the double coil 212.

That is, in the double coil 212, the first coil 212a and the second coil 212b are provided with the power feeding points 303 and 305, respectively, and are supplied with the high frequency powers from the high frequency power supplies 273 and 283, respectively. Further, the amplitude of the standing wave of the high frequency current is maximized in the vicinity of each of the electrical midpoint of the first coil 212a and the grounding point 304 and in the vicinity of each of the electrical midpoint of the second coil 212b and the grounding point 306. That is, at the electrical midpoint of each of the two coils of the double coil 212 and the grounding points 304 and 306 in the double coil 212, the amplitude of the standing wave of the high frequency voltage is minimized (ideally zero) and the amplitude of the standing wave of the high frequency current is maximized.

In the vicinity of the electrical midpoints of the first coil 212a and the second coil 212b, where the amplitude of the high frequency current is maximized, a high frequency magnetic field is strongly formed, and the process gas supplied into the plasma generation space 201a in the upper vessel 210 is converted into the plasma state. That is, by the high frequency magnetic field formed in the vicinity of the positions (regions) where the amplitude of the high frequency current is great, the process gas is converted into the plasma state (also referred to as an “inductively coupled plasma” or an “ICP”). The ICP is generated in a donut shape in the regions in the vicinity of the electrical midpoints of the first coil 212a and the second coil 212b in a space along a surface of an inner wall of the upper vessel 210, and diffuses in a direction of the wafer 200. Thereby, it is possible to uniformly form the plasma within the surface of the substrate (that is, the wafer 200).

### <Controller>

A controller 221 serving as a control structure is configured to be capable of respectively controlling: the APC valve 242, the valve 243b and the vacuum pump 246 through a signal line “A”; the susceptor elevator 268 through a signal line “B”; a heater power regulator 276 and the variable impedance regulator 275 through a signal line “C”; the gate valve 244 through a signal line “D”; the RF sensors 272 and 282, the high frequency power supplies 273 and 283 and the matchers 274 and 284 through a signal line “E”; and the MFCs 252a, 252b and 252c and the valves 253a, 253b, 253c and 243a through a signal line “F”.

As shown in FIG. 5, the controller 221 serving as the control structure (control apparatus) is constituted by a computer including a CPU (Central Processing Unit) 221a, a RAM (Random Access Memory) 221b, a memory 221c and an I/O port 221d. The RAM 221b, the memory 221c and the I/O port 221d are configured to be capable of exchanging data with the CPU 221a through an internal bus 221e. For example, an input/output device 225 constituted by components such as a touch panel and a display may be connected to the controller 221.

The memory 221c may be embodied by a component such as a flash memory and a hard disk drive (HDD). For example, a control program configured to control operations of the substrate processing apparatus 100 and a process recipe in which information such as sequences and conditions of the substrate processing described later is stored may be readably stored in the memory 221c. The process recipe is obtained by combining steps of the substrate processing described later such that the controller 221 can execute the steps to acquire a predetermined result, and functions as a program. Hereinafter, the process recipe and the control program may be collectively or individually referred to as a “program”. Thus, in the present specification, the term “program” may refer to the process recipe alone, may refer to the control program alone, or may refer to both of the process recipe and the control program. Further, the RAM 221b functions as a memory area (work area) where a program or data read by the CPU 221a is temporarily stored.

The I/O port 221d is electrically connected to the components described above such as the MFCs 252a, 252b and 252c, the valves 253a, 253b and 253c, 243a and 243b, the gate valve 244, the APC valve 242, the vacuum pump 246, the heater 217b, the RF sensors 272 and 282, the high frequency power supplies 273 and 283, the matchers 274 and 284, the susceptor elevator 268, the variable impedance regulator 275 and the heater power regulator 276.

The CPU 221a is configured to read and execute the control program stored in the memory 221c, and to read the process recipe stored in the memory 221c in accordance with an instruction such as an operation command inputted via the input/output device 225. In addition, the CPU 221a is configured to be capable of controlling various operations, in accordance with the read process recipe, such as an operation of adjusting an opening degree of the APC valve 242, an opening and closing operation of the valve 243b and a start and stop of the vacuum pump 246 via the I/O port 221d and the signal line “A”, an elevating and lowering operation of the susceptor elevator 268 via the I/O port 221d and the signal line “B”, a power supply amount adjusting operation (temperature adjusting operation) to the heater 217b by the heater power regulator 276 and an impedance value adjusting operation by the variable impedance regulator 275 via the I/O port 221d and the signal line “C”, an opening and closing operation of the gate valve 244 via the I/O port 221d and the signal line “D”, controlling operations for the RF sensors 272 and 282, the matchers 274 and 284 and the high frequency power supplies 273 and 283 via the I/O port 221d and the signal line “E”, and flow rate adjusting operations for various gases by the MFCs 252a, 252b and 252c and opening and closing operations of the valves 253a, 253b, 253c and 243a via the I/O port 221d and the signal line “F”.

The controller 221 may be embodied by installing the above-mentioned program stored in an external memory 226 (for example, a magnetic tape, a magnetic disk such as a flexible disk and a hard disk, an optical disk such as a CD and a DVD, a magneto-optical disk such as an MO and a semiconductor memory such as a USB memory and a memory card) into the computer. The memory 221c or the external memory 226 may be embodied by a non-transitory computer readable recording medium. Hereafter, the memory 221c and the external memory 226 may be collectively or individually referred to as a “recording medium”. Thus, in the present specification, the term “recording medium” may refer to the memory 221c alone, may refer to the external memory 226 alone, or may refer to both of the memory 221c and the external memory 226. The program may be provided to the computer without using the external memory 226. For example, the program may be supplied to the computer using a communication structure such as the Internet and a dedicated line.

### (2) Substrate Processing

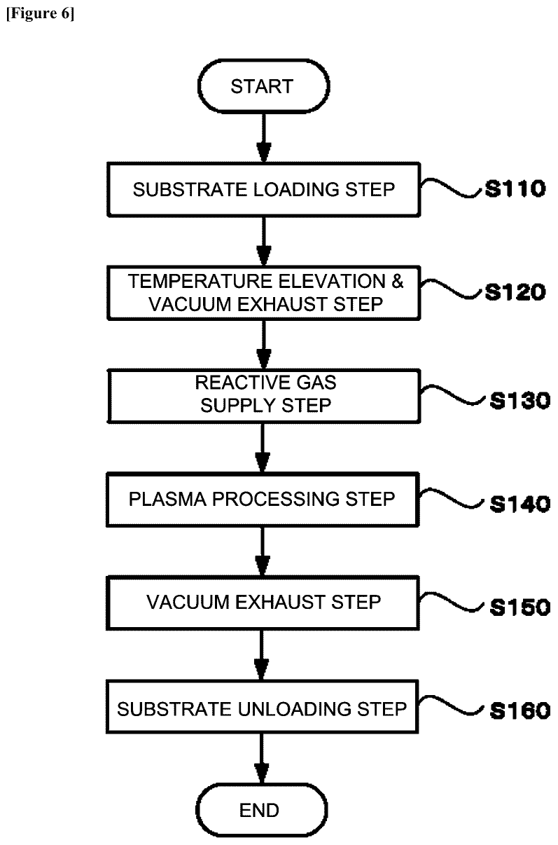

Subsequently, the substrate processing according to the embodiment of the present disclosure will be described mainly with reference to FIG. 6. FIG. 6 is a flow chart schematically illustrating the substrate processing according to the embodiment of the present disclosure. The substrate processing according to the embodiment of the present disclosure, which is a part of a manufacturing process of the semiconductor device such as a flash memory, is performed by using the substrate processing apparatus 100 described above. In the following description, operations of components constituting the substrate processing apparatus 100 are controlled by the controller 221.

Further, although not shown, a trench which includes a concave-convex portion of a high aspect ratio is formed in advance on the surface of the wafer 200 to be processed by the substrate processing according to the embodiment of the present disclosure. According to the embodiment of the present disclosure, for example, an oxidation process serving as a process using the plasma is performed with respect to a silicon (Si) layer exposed on an inner wall of the trench.

### <Substrate Loading Step S110>

First, the wafer 200 is transferred (loaded) into the process chamber 201. Specifically, the susceptor 217 is lowered to a transfer position of the wafer 200 by the susceptor elevator 268 such that the wafer lift pins 266 pass through the through-holes 217a of the susceptor 217. As a result, the wafer lift pins 266 protrude from the through-holes 217a by a predetermined height above a surface of the susceptor 217.

Subsequently, the gate valve 244 is opened, and the wafer 200 is loaded into the process chamber 201 using the wafer transfer structure (not shown) from a vacuum transfer chamber (not shown) provided adjacent to the process chamber 201. The wafer 200 loaded into the process chamber 201 is placed on and supported by the wafer lift pins 266 (which protrude from the surface of the susceptor 217) in a horizontal orientation. After the wafer 200 is loaded into the process chamber 201, the wafer transfer structure is retracted to a position outside the process chamber 201, and the gate valve 244 is closed to hermetically seal (or close) an inside of the process chamber 201. Thereafter, by elevating the susceptor 217 using the susceptor elevator 268, the wafer 200 is placed on and supported by an upper surface of the susceptor 217.

### <Temperature Elevation and Vacuum Exhaust Step S120>

Subsequently, a temperature of the wafer 200 loaded into the process chamber 201 is elevated. The heater 217b is heated in advance, and the wafer 200 is heated to a predetermined temperature (for example, a temperature within a range from 25° C. to 800° C.) by placing the wafer 200 on the susceptor 217 where the heater 217b is embedded. Further, while the temperature of the wafer 200 is being elevated, the vacuum pump 246 vacuum-exhausts the inside of the process chamber 201 through the gas exhaust pipe 231 such that an inner pressure of the process chamber 201 reaches and is maintained at a predetermined pressure. The vacuum pump 246 is continuously operated at least until a substrate unloading step S160 described later is completed.

### <Reactive Gas Supply Step S130>

Subsequently, as a supply of a reactive gas (process gas) a supply of the oxygen-containing gas and a supply of the hydrogen-containing gas into the process chamber 201 are started. Specifically, the valve 253a and the valve 253b are opened to start the supply of the oxygen-containing gas and the supply of the hydrogen-containing gas into the process chamber 201 while flow rates of the oxygen-containing gas and the hydrogen-containing gas are adjusted by the MFCs 252a and 252b, respectively. In the present step, for example, the flow rate of the oxygen-containing gas is adjusted (or set) to a predetermined value within a range from 20 sccm to 2,000 sccm. In addition, for example, the flow rate of the hydrogen-containing gas is adjusted (or set) to a predetermined value within a range from 20 sccm to 1,000 sccm.

Further, for example, an exhaust of the inside of the process chamber 201 is controlled by adjusting the opening degree of the APC valve 242 such that the inner pressure of the process chamber 201 reaches and is maintained at a predetermined pressure within a range from 1 Pa to 250 Pa. While appropriately exhausting the inside of the process chamber 201 in a manner described above, the oxygen-containing gas and the hydrogen-containing gas are continuously supplied into the process chamber 201 until a plasma processing step S140 described later is completed.

For example, as the oxygen-containing gas, a gas such as oxygen (O₂) gas, nitrous oxide (N₂O) gas, nitrogen monoxide (NO) gas, nitrogen dioxide (NO₂) gas, ozone (O₃) gas, water vapor (H₂O) gas, carbon monoxide (CO) gas and carbon dioxide (CO₂) gas may be used. One or more of the gases described above may be used as the oxygen-containing gas.

In addition, for example, as the hydrogen-containing gas, a gas such as hydrogen (H₂) gas, deuterium (D₂) gas, the H₂O gas and ammonia (NH₃) gas may be used. One or more of the gases described above may be used as the hydrogen-containing gas. When the H₂O gas is used as the oxygen-containing gas, it is preferable that a gas other than the H₂O gas is used as the hydrogen-containing gas. In addition, when the H₂O gas is used as the hydrogen-containing gas, it is preferable that a gas other than the H₂O gas is used as the oxygen-containing gas.

For example, as the inert gas, nitrogen (N₂) gas may be used. Instead of or in addition to the nitrogen gas, a rare gas such as argon (Ar) gas, helium (He) gas, neon (Ne) gas and xenon (Xe) gas may be used as the inert gas. For example, one or more of the gases described above may be used as the inert gas.

### <Plasma Processing Step S140>

When the inner pressure of the process chamber 201 is stabilized, an application of the high frequency power to the first coil 212a and an application of the high frequency power to the second coil 212b are started simultaneously from the high frequency power supplies 273 and 283 via the RF sensors 272 and 282 and the matchers 274 and 284, respectively.

Thereby, a high frequency electric field is formed in the plasma generation space 201a to which the oxygen-containing gas and the hydrogen-containing gas are supplied. Thereby, a donut-shaped ICP whose plasma density is the highest at a height position corresponding to each of the electrical midpoints of the first coil 212a and the second coil 212b in the plasma generation space 201a can be excited by the high frequency electric field. Further, when both ends of the first coil 212a and both ends of the second coil 212b are grounded, the ICP is also excited at the height positions of the respective lower and upper ends. Each of the oxygen-containing gas and the hydrogen-containing gas is excited into the plasma state and dissociates. As a result, reactive species such as oxygen radicals containing oxygen (oxygen active species), oxygen ions, hydrogen radicals containing hydrogen (hydrogen active species) and hydrogen ions can be generated.

The radicals generated by the induction plasma (that is, the ICP) are uniformly supplied into the trench of the wafer 200 placed on the susceptor 217 in the substrate processing space 201b. Then, the radicals uniformly supplied into the trench of the wafer 200 react uniformly with a layer (for example, the silicon layer) formed on a side wall of the trench. Thereby, the layer formed on the side wall of the trench is modified into an oxide layer (for example, a silicon oxide layer) whose step coverage is enhanced.

After a predetermined process time (for example, 10 seconds to 300 seconds) has elapsed, outputs of the high frequency power from the high frequency power supplies 273 and 283 are stopped to stop a plasma discharge in the process chamber 201. In addition, the valve 253a and the valve 253b are closed to stop the supply of the oxygen-containing gas and the supply of the hydrogen-containing gas into the process chamber 201. Thereby, the plasma processing step S140 is completed.

### <Vacuum Exhaust Step S150>

After the supply of the oxygen-containing gas and the supply of the hydrogen-containing gas are stopped, the inside of the process chamber 201 is vacuum-exhausted through the gas exhaust pipe 231. Thereby, a gas such as the oxygen-containing gas, and the hydrogen-containing gas and an exhaust gas generated from a reaction therebetween in the process chamber 201 can be exhausted out of the process chamber 201. Thereafter, the opening degree of the APC valve 242 is adjusted such that the inner pressure of the process chamber 201 is adjusted to the same pressure as that of the vacuum transfer chamber (to which the wafer 200 is to be transferred: not shown) provided adjacent to the process chamber 201.

### <Substrate Unloading Step S160>

After the inner pressure of the process chamber 201 is adjusted to a predetermined pressure, the susceptor 217 is lowered to the transfer position of the wafer 200 until the wafer 200 is supported by the wafer lift pins 266. Then, the gate valve 244 is opened, and the wafer 200 is transferred (unloaded) out of the process chamber 201 by using the wafer transfer structure (not shown).

Thereby, the substrate processing according to the embodiment of the present disclosure is completed.

### (3) Modified Examples

The double coil 212 according to the embodiment described above may be modified as shown in the following modified examples. Unless otherwise described, a configuration in each of the modified examples is substantially the same as a configuration in the embodiment described above, and the description of each of the modified examples will be omitted.

### <First Modified Example>

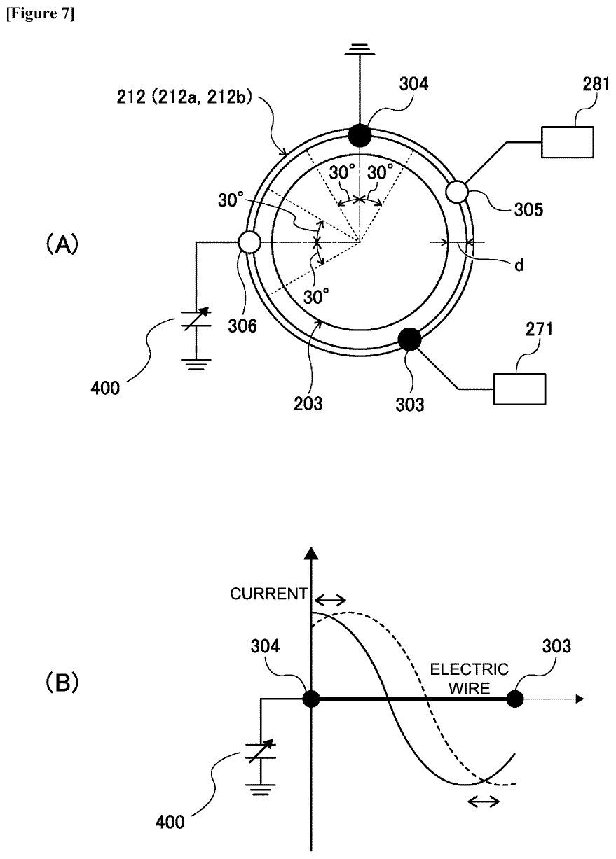

A first modified example will be described using FIGS. 7A and 7B. According to the present modified example, a structure (which is a device) 400 containing an appropriate impedance is connected to the end position of the spiral of at least one of the first coil 212a or the second coil 212b constituting the double coil 212 described above, and grounded. Specifically, for example, the structure 400 containing the appropriate impedance is connected to the grounding point 306 of the second coil 212b, and grounded.

Further, by adjusting the impedance of the structure 400, it is possible to adjust a position where the standing wave is generated in the second coil 212b, and it is also possible to adjust a peak position of the high frequency current. That is, as shown in FIG. 7B, the peak position of the high frequency current of the standing wave of the second coil 212b (indicated by a broken line in FIG. 7B) is adjusted so as to be shifted from the peak position of the high frequency current of the standing wave of the first coil 212a (indicated by a solid line in FIG. 7B). Thereby, it is possible to suppress the local increase in the maximum amplitude obtained by the superposition of the standing waves.

By connecting the structure 400 containing the appropriate impedance to the grounding point of one coil of the double coil 212 in a manner described above, similar to the embodiment described above, it is possible to suppress the local increase in the maximum amplitude obtained by the superposition of the standing waves. Further, by reducing the damage caused by the plasma to the quartz component and the like in the process vessel 203 made of quartz or the like of the process chamber 201 and the like, it is also possible to improve the uniformity of the substrate processing within the surface of the substrate (that is, the wafer 200).

### Second Modified Example

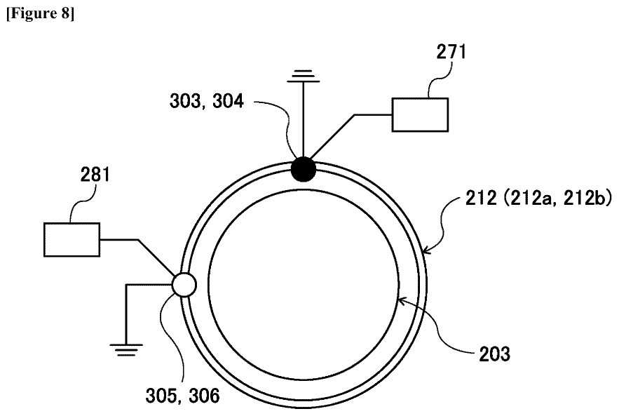

A second modified example will be described using FIG. 8. According to the present modified example, in the double coil 212, the grounding point 306 of the second coil 212b is rotated from the grounding point 304 of the first coil 212a, for example, by 90° around the center axis of the inner diameter of the double coil 212 as the rotation axis. Further, the positions of the power feeding point 303 and the grounding point 304 of the first coil 212a are set to be substantially the same in the circumferential direction, and are arranged at different positions in the vertical direction. In addition, the positions of the power feeding point 305 and the grounding point 306 of the second coil 212b are set to be substantially the same in the circumferential direction, and are arranged at different positions in the vertical direction. In the present specification, the term “the positions of the power feeding point and the grounding point of each coil are set to be substantially the same” means that the positions of the feeding point and the grounding point of each coil in the circumferential direction are substantially the same within an error range of about ±10%. That is, the power feeding point 303 and the grounding point 304 of the first coil 212a are arranged on the same side in the circumferential direction of the double coil 212, and the power feeding point 305 and the grounding point 306 of the second coil 212b are arranged on the same side in the circumferential direction of the double coil 212.

Further, the diameters and lengths of the first coil 212a and the second coil 212b are set to be substantially the same, and the first coil 212a and the second coil 212b are configured to be wound along the outer periphery of the process vessel 203 the same odd number of times. As a result, in each of the first coil 212a and the second coil 212b, it is possible to arrange the peak value of the high frequency current at the electrical midpoint on an opposite side (opposing side) of the power feeding point and the grounding point, and it is also possible to disperse the peak value of the high frequency current in the standing wave. Therefore, the peak position of the high frequency current of the standing wave is configured so as not to overlap between the first coil 212a and the second coil 212b. That is, similar to the embodiment described above, it is possible to suppress the local increase in the maximum amplitude obtained by the superposition of the standing waves. Further, by reducing the damage caused by the plasma into the process vessel 203 made of the quartz and the like of the process chamber 201, it is also possible to improve the uniformity of the substrate processing within the surface of the substrate (that is, the wafer 200). Further, it is possible to easily perform a control of suppressing the occurrence of the abnormal discharge.

### Other Embodiments

While the technique of the present disclosure is described in detail by way of the embodiment and the modified examples described above, the technique of the present disclosure is not limited thereto. The technique of the present disclosure may be applied even when the embodiment and the modified examples described above are appropriately combined.

Further, while the embodiment described above is described by way of an example in which the double coil 212 constituted by the first coil 212a and the second coil 212b is used, the technique of the present disclosure is not limited thereto. For example, the technique of the present disclosure may be applied even when a coil constituted by three or more coils is used. In such a case, the coil constituted by three or more coils may also be referred to as a “plasma generation structure of three or more coils”.

For example, while the embodiment described above is described by way of an example in which the oxidation process is performed onto the surface of the substrate by using the plasma, the technique of the present disclosure may also be applied to a nitridation process using a nitrogen-containing gas as the process gas. Further, the technique of the present disclosure may also be applied to an etching process using an etching gas such as a fluorine-containing gas or a chlorine-containing gas as the process gas. Further, the technique of the present disclosure is not limited thereto, and may also be applied to other processing techniques of processing the substrate by using the plasma where at least one gas selected from the group of the oxygen-containing gas, the nitrogen-containing gas, the hydrogen-containing gas, the fluorine-containing gas and the chlorine-containing gas is capable of being used as the process gas. For example, the technique of the present disclosure may be applied to a process such as a modification process onto a film formed on the surface of the substrate, a doping process, a reduction process of an oxide film, an etching process with respect to the film and an ashing process for a photoresist, which are performed by using the plasma. With such a configuration described above, it is possible to increase the plasma density, it is also possible to further increase a processing speed, and it is also possible to form a film to which the modification process is further performed.

In addition, while the technique of the present disclosure is described in detail by way of the embodiment and the modified examples described above, the technique of the present disclosure is not limited thereto. It will be apparent to those skilled in the art that the technique of the present disclosure may be modified in various ways without departing from the scope thereof.

### DESCRIPTION OF REFERENCE NUMERALS

200 wafer (substrate)
203 process vessel
212 double coil
212a first coil
212b second coil
271, 281 high frequency power supplier

1. A substrate processing apparatus comprising:
a process vessel in which a process gas is excited into a plasma state;
a gas supplier configured to supply the process gas into the process vessel; and
a plasma generation structure provided so as to be wound in a spiral shape along an outer periphery of the process vessel and comprising at least two coils to which high frequency powers are respectively supplied,
wherein diameters of the at least two coils are set to be substantially same, lengths of the at least two coils are set to be substantially same, and a net amplitude obtained by superposition of standing waves respectively generated by the at least two coils is set to be smaller than a peak amplitude of each of the standing waves.

2. The substrate processing apparatus of claim 1, wherein end positions of spirals of the at least two coils are arranged such that a circumferential range of ±30° from an end position of a spiral of each of the at least two coils does not overlap with that of a spiral of any other one of the at least two coils.

3. The substrate processing apparatus of claim 1, wherein a structure containing an impedance is connected to an end position of a spiral of at least one among the at least two coils.

4. The substrate processing apparatus of claim 1, wherein the at least two coils are configured to be wound along the outer periphery of the process vessel a same odd number of times.

5. The substrate processing apparatus of claim 1, wherein at least one gas selected from the group of an oxygen-containing gas, a nitrogen-containing gas, a hydrogen-containing gas, a fluorine-containing gas and a chlorine-containing gas is capable of being used as the process gas.

6. The substrate processing apparatus of claim 3, wherein a peak position of a high frequency current is configured to be capable of being adjusted by adjusting the impedance of the structure.

7. A method of manufacturing a semiconductor device by using a substrate processing apparatus comprising a plasma generation structure comprising at least two coils to which high frequency powers are respectively supplied and provided so as to be wound in a spiral shape along an outer periphery of a process vessel, wherein diameters of the at least two coils are set to be substantially same, lengths of the at least two coils are set to be substantially same, and a net amplitude obtained by superposition of standing waves respectively generated by the at least two coils is set to be smaller than a peak amplitude of each of the standing waves, the method comprising:
(a) supplying a process gas into the process vessel;
(b) supplying the high frequency powers respectively to the at least two coils to excite the process gas supplied into the process vessel into a plasma state; and
(c) supplying the process gas excited into the plasma state onto a substrate to process the substrate.

8. A substrate processing method using a substrate processing apparatus comprising a plasma generation structure comprising at least two coils to which high frequency powers are respectively supplied and provided so as to be wound in a spiral shape along an outer periphery of a process vessel, wherein diameters of the at least two coils are set to be substantially same, lengths of the at least two coils are set to be substantially same, and a net amplitude obtained by superposition of standing waves respectively generated by the at least two coils is set to be smaller than a peak amplitude of each of the standing waves, the substrate processing method comprising:
(a) supplying a process gas into the process vessel;
(b) supplying the high frequency powers respectively to the at least two coils to excite the process gas supplied into the process vessel into a plasma state; and
(c) supplying the process gas excited into the plasma state onto a substrate to process the substrate.

9. The substrate processing apparatus of claim 1, wherein the high frequency powers are supplied to the at least two coils simultaneously.

10. The substrate processing apparatus of claim 1, wherein the at least two coils are operated simultaneously.

11. The substrate processing apparatus of claim 1, wherein the process vessel comprises:
a plasma generation space around which the at least two coils are provided; and
a substrate processing space arranged below the plasma generation space.

12. The substrate processing apparatus of claim 11, wherein the plasma generation space is located above lower ends of the at least two coils, and the substrate processing space is located below the lower ends of the at least two coils.

13. The substrate processing apparatus of claim 1, wherein the at least two coils are arranged alternately at equal intervals in a vertical direction.

14. The substrate processing apparatus of claim 1, wherein lengths of the at least two coils from respective power feeding points to respective grounding points are set to be substantially same within an error range of ±10%.

15. The substrate processing apparatus of claim 1, wherein wire diameters of the at least two coils are set to be substantially same within an error range of ±10%.

16. The substrate processing apparatus of claim 1, wherein the at least two coils comprise a first coil and a second coil, a winding diameter of the first coil is substantially same as that if the second coil, and a distance from a surface of an outer wall of the process vessel to an inner peripheral surface of the first coil and a distance from the surface of the outer wall of the process vessel to an inner peripheral surface of the second coil are set to be constant.

17. The substrate processing apparatus of claim 1, wherein end positions of the at least two coils are located at angular positions ±90° or ±180° away from each other.

18. The substrate processing apparatus of claim 1, wherein electrical midpoints of the at least two coils are arranged at different positions in a circumferential direction.

19. The substrate processing apparatus of claim 1, wherein the at least two coils comprise a first coil and a second coil, and
wherein, in a state where the first coil and the second coil are arranged in a manner that a circumferential position of an electrical midpoint of the first coil is deviated from that of an electrical midpoint of the second coil, a circumferential position of a power feeding point of the first coil is substantially same as that of a grounding point of the first coil, and a circumferential position of a power feeding point of the second coil is substantially same as that of a grounding point of the second coil.

20. A non-transitory computer-readable recording medium storing a program that causes a substrate processing apparatus, by a computer, to perform a process comprising the substrate processing method of claim 8.
